(19) United States
(12) Patent Application Publication
(10) Pub. No.: US 2011/0250392 A1
(43) Pub. Date: Oct. 13, 2011

(54) Substrate with Planarizing Coating and Method of Making Same

(76) Inventors: Joseph W. Woody, V., St. Paul, MN (US); William Blake Kolb, St. Paul, MN (US); Brant U. Kolb, St. Paul, MN (US)

(21) Appl. No.: 13/133,049

(22) PCT Filed: Dec. 28, 2009
(86) PCT No.: PCT/US2009/069564

§ 371 Date: Jun. 6, 2011

Related U.S. Application Data
(60) Provisional application No. 61/141,849, filed on Dec. 31, 2008.

(51) Int. Cl. B32B 3/00; B05D 5/02; B05D 3/12; B05D 3/10; B32B 15/082; B32B 27/30

(52) U.S. Cl. 428/141; 428/463; 428/522; 427/355; 427/299; 427/256

(57) ABSTRACT

A substrate coated with a composition so as to form a planarizing layer defining a planarized surface of the substrate having an RMS surface roughness equal to or less than about 1 nm. The composition comprises in polymerized form at least one or more acrylate containing monomers, oligomers, or resins and a plurality of inorganic oxide particles that are smaller than or equal to 20 nm in size.

The present invention relates to planarized surfaces, in particular, to coatings used to planarize surfaces, and more particularly, to polymeric planarization coatings for planarizing a substrate surface so as to exhibit an RMS surface roughness equal to or less than about 1 nm. The present invention also relates to a method of planarizing a surface of a substrate.

### BACKGROUND

The development of coated polymeric substrates for optical and/or electrical devices is well documented in the art. For certain of these applications, it is desirable for one or more of the substrate surfaces to be very smooth (i.e. to have very low surface roughness values). It is known to use planarizing coatings to obtain smooth surfaces on such polymeric substrates. One type of planarizing coating is disclosed in U.S. Patent Publication No. 2005/0238871.

Even though planarizing coatings are available, there is a continuing need for alternatives and improvements to such coatings. The present invention provides such an alternative planarizing coating.

### SUMMARY OF THE INVENTION

It has been discovered that by including inorganic oxide (e.g., silica) particles having a size less than or equal to 20 nm into the composition of an acrylate-based planarization coating, the surface smoothness (i.e., lower surface roughness values) of the coating can be unexpectedly improved, as compared to the same composition without such particles. It has also been discovered that such unexpected improvements in surface smoothness can be obtained with relatively low concentrations (i.e., loadings) of the inorganic oxide particles.

In one aspect of the present invention, a substrate is provided that is coated with a composition so as to form a planarizing layer defining a planarized surface of the substrate having an RMS surface roughness equal to or less than about 1 nm. The composition comprises in polymerized form at least one or a blend of two or more acrylate containing monomers, oligomers, or resins and a plurality of inorganic oxide particles that are smaller than or equal to 20 nm in size. A number of optional features can be employed in practicing the present inventive substrate, including the following.

The planarized surface of the substrate can have an RMS surface roughness equal to or less than 0.7 nm. The composition can comprise at least about 5% by weight of the inorganic oxide particles. It is believed that the inorganic oxide particles can be of a size within a range of from about 1 nm up to about 10 nm. Desirable results have been obtained using inorganic oxide particles that comprise silica particles, and in particular colloidal silica particles, preferably having a size of about 5 nm and being in concentrations in the range of from about 5% to about 40% by weight. It is desirable for the composition, in its pre-polymerized form, to be radiation curable. The planarized surface of the planarization layer can have a hardness of about 4H or harder. The planarized surface of the planarization layer can be further coated with at least one of a metallic layer and a barrier layer.

In another aspect of the present invention, a method of planarizing a surface of a substrate is provided. The method comprises providing a substrate having a major surface, and a composition comprising at least one or a blend of two or more acrylate containing monomers, oligomers, or resins and a plurality of inorganic oxide particles that are smaller than or equal to 20 nm in size. The major surface of the substrate is coated with the composition, and the coated composition is polymerized so as to form a planarizing layer defining a planarized surface having an RMS surface roughness equal to or less than about 1 nm. A number of optional features can be employed in practicing the present inventive method, including the following.

The planarized surface being formed can have an RMS surface roughness equal to or less than 0.7 nm. Desirable results have been obtained when the composition being coated comprises inorganic oxide particles in the form of a dispersion of colloidal particles, in particular when the colloidal particles comprise silica particles. The method can further comprise radiation curing the coated composition, when the composition is a radiation curable composition. If desired, the coated composition can be processed through a drying operation, before being cured. When the substrate is a flexible web substrate of indefinite length, the present method can comprise coating the major surface of the web substrate with the composition while the web substrate is moving in a direction parallel to its longitudinal axis (e.g., upstream or downstream in a web handling process). The present method can further comprise coating the planarized surface with at least one of a metallic layer and a barrier layer.

The present method can also include cleaning the major surface of the substrate before it is coated with the composition. For example, the major surface of the substrate can be cleaned so as to be at least substantially free of particles having a size as small as 3 microns, and possibly even smaller, as well as particles larger than 3 microns. A co-pending and co-assigned US Provisional Patent Application entitled METHOD OF PRODUCING A COMPONENT OF A DEVICE, AND THE RESULTING COMPONENTS AND DEVICES, corresponding to Attorney Docket Number 64114US002, which was filed on Dec. 31, 2008 along with the present application, discloses such a cleaning process and is hereby incorporated by reference herein, in its entirety.

### DETAILED DESCRIPTION OF ILLUSTRATIVE EMBODIMENTS

In describing preferred embodiments of the invention, specific terminology is used for the sake of clarity. The invention, however, is not intended to be limited to the specific terms so selected, and each term so selected includes all technical equivalents that operate similarly.

A substrate according to the present invention can include, for example, a flexible web of indefinite length, a plate, sheet or other structure. The substrate is coated with a composition so as to form a planarizing layer defining a planarized surface of the substrate having an average Ra and/or Rq root mean square (RMS) surface roughness equal to or less than about 1 nm, equal to or less than about 0.9 nm, equal to or less than about 0.8 nm, equal to or less than about 0.7 nm, equal to or less than about 0.6 nm, equal to or less than about 0.5 nm, equal to or less than about 0.4 nm, or equal to or less than about 0.3 nm, as measured over a scan area of about 25 microns, using atomic force microscopy (AFM). The composition comprises in polymerized form at least one and preferably a blend of two or more acrylate containing monomers, oligomers, or resins and a plurality (i.e., at least about 1%, 5%, 10%, 20%, 30%, 40%, 50% by weight or more) of inorganic oxide particles that are smaller than or equal to 20 nm in size. In other embodiments, the inorganic oxide particles are of a size equal to or larger than 1 nm and either equal to or smaller than 15 nm in size, equal to or smaller than 10 nm in size, or equal to or smaller than 5 nm in size.

As used herein, and unless otherwise expressly stated to the contrary, a reference to one or more acrylate containing monomers also refers to one or more (methyl)acrylate containing monomers. A “web”, as used herein, consists of or at least comprises a polymeric film or layer that can be planarized according to the present invention. The web may further comprise a reinforcing backing (e.g., a fiber reinforced film, woven or non-woven scrim, fabric, etc.) for the polymeric film or layer. A web that is “flexible” is one that can be wound into a roll. A web of “indefinite length” refers to a web that is much longer than it is wide. As used here, the singular use of the term “planarizing layer” includes one or multiple layers of any composition used according to the present invention to provide a very smooth planarized surface when coated onto a substrate.

The planarization layers of this invention generally have a thickness in the range of from about 0.5 microns to about 100 microns. The present planarization layers can also have thicknesses in the range of from about 1 microns to about 50 microns. It can be desirable for the present planarization layers to have a thickness in the range of from about 3 microns to about 25 microns. It can also be desirable for the present planarization layers to have a thickness in the range of from about 3 microns to about 10 microns.

Desirable results have been obtained using coating compositions comprising blends of acrylate containing monomers and silica particles of about 5 nm in size and loaded in concentrations in the range of from about 5% to about 40% by weight. It is believed that larger silica particles greater than 5 nm in size and less than or equal to 20 nm in size will perform similarly. It is also believed that similar or at least satisfactory results may be obtained using zirconia, titania and other inorganic oxide particles of a similar range of sizes. Satisfactory results have also been obtained using radiation (e.g. ultraviolet light or other actinic radiation) curable compositions for the planarizing layer. The prepolymerized composition can be a non-aqueous dispersion, or a 100% solids formulation, of one or more acrylate or (methyl)acrylate containing monomers and inorganic oxide particles.

Table of Chemicals Used in Examples

| Abbreviation or Trade | |
|---|---|
| Designation | Description |
| MEEAA | 2-(2-(2-Methoxyethoxy) Ethoxy) Acetic Acid available |
| | form Aldrich Chemical Company (Milwaukee, WI) |
| DI water | De-ionized water |
| PROSTABB 5198 | A radical inhibitor that is commercially available from |
| | Ciba Specialties (Hawthorne, NY) |
| 1-Methoxy-2-propanol | An alcohol that is commercially available from Aldrich |
| | Chemical (Milwaukee, WI) |
| SR444 | Pentaerythritol Triacrylate that is commercially available |
| | from Sartomer Company Inc. (Exton PA) |
| SR238 | 1,6 Hexanediol Diacrylate that is commercially available |
| | from Sartomer Company Inc. (Exton PA) |
| SR506 | Isobornylacrylate that is commercially available from |
| | Sartomer Company Inc. (Exton PA) |
| Resin 1 | A mixture containing 40/40/20 weight percent |
| | SR444/SR238/SR506 |
| SR494 | Ethoxylated Pentaerythritol Tetraacrylate that is |
| | commercially available from Sartomer Company Inc. |
| | (Exton PA) |
| 2-Hydroxyethyl acrylate | An acrylate monomer that is commercially available |
| | from Aldrich Chemical Company (Milwaukee, WI) |
| Triethylamine | A base that is commercially available from Aldrich |
| | Chemical Company (Milwaukee, WI) |
| Maleic anhydride | Commercially available from Aldrich Chemical |
| | Company (Milwaukee, WI) |
| Nalco 2326 | Colloidal silica dispersion available from Nalco Co. |
| | Naperville IL. 5 nm silica at 15 wt % in water. |
| 2,6-Di-tert-butyl-4- | Available from Aldrich Chemical Milwaukee WI |
| methyphenol | |
| Phenothiazine | Available from Aldrich Chemical Milwaukee WI |
| BS1316 | Isooctyltrimethoxy Silane available from Wacker |
| | Silicones, Germany |
| (2-Cyanoethyl)triethoxysilane | Available from Alfa Asar (WardHill, MA) |
| 3- | Available from Aldrich Chemical Milwaukee WI |
| (Methacryloyloxy)propyltrim | |
| ethoxysilane | |
| Silquest A1230 | Proprietary nonionic silane available from Crompton OSI |
| | Specialties (Middlebury, CT) |
| MEK | Methyl Ethyl Ketone available through Mallinckrodt |
| | Baker Inc., Phillipsburg, NJ |
| IPA | Isopropyl Alcohol available through EMD Chemicals |
| | Inc. Gibbstown, NJ |
| Toluene | Available through EMD Chemicals Inc. Gibbstown, NJ |
| IPA/Tol | A 30/70 weight percent blend of IPA and Toluene |

Preparation of maleic acid mono-(2-acryloyloxy-ethyl) ester (HEAS) Phthalic anhydride (74.12 grams), 2-hydroxyethyl acrylate (87.9 grams) and triethylamine (0.44 grams) were mixed in a round bottom flask. A small amount of dry air was bubbled into the liquid. The reaction mixture was mixed and heated to 75 degrees C. and held at that temperature for six hours. Thereafter, the product was cooled to room temperature and NMR (Nuclear Magnetic Resonance) was used to confirm that the product was maleic acid mono-(2-acryloyloxy-ethyl) ester. The product was mixed with 1-methoxy-2-propanol to prepare a 50 weight percent solution.

### Example 1

A planarization coating composition, according to the present invention, was prepared that included a blend of three different acrylate monomers, all commercially available from Sartomer Co. of Exton, Pa. The blend was a 40:40:20 mixture of the Sartomer monomers SR-444, SR-238 and SR-506 respectively. SR-444 is a pentaerythritol triacrylate having a Tg equal to about 103° C., SR-238 is a 1,6-hexanediol diacrylate having a Tg equal to about 43° C., and SR-506 is an isobornyl acrylate having a Tg in the range of from about 88° C. to about 94° C. This blend of acrylate monomers was 58% by weight of the total composition of the coating material. Another 1% by weight of the total composition was a 2,4,6-trimethylbenzoyldiphenylphosphinate photoinitiator commercially available as Lucirin® TPO-L from BASF of Ludwigshafen, Germany. Approximately 41% by weight of the coating composition was surface treated Nalco 2326 silica sol commercially available from the Nalco Chemical Co. of Naperville, Ill. The Nalco 2326 silica particles have a mean particle size of 5 nm, a pH of 10.5, and a solid content of 15% by weight.

The Nalco 2326 particles were surface treated by first charging about 400 grams into a 1 quart jar 1-methoxy-2-propanol (450 g), 3-(Methacryloyloxy)propyltrimethoxysilane (27.82 g) and Prostabb (0.17 g of 5 wt % solution in water) were mixed together and added to the colloidal dispersion while stirring. The jar was sealed and heated to 80 degrees C. for 16 hours.

The above surface modified silica dispersion (about 820 grams), resin 1 (about 98 g), and a 5% solution of Prostabb (about 0.75 g) were combined and mixed. The water and 1-methoxy-2-propanol were removed from the mixture via rotary evaporation to give a total resin weight of about 170 g. For the purpose of viscosity adjustment at the time of coating, the composition was diluted to 50:50 ratio by weight with methyl-ethyl ketone (MEK).

A slot die coater, having a slot width of 4 inches (102 mm) and a slot height of 0.005 inch (0.13 mm), was used to coat the composition of Example 1 onto a film substrate. In particular, the coating composition was fed by syringe pump at a rate of about 2 cm³/minute onto a polyester terephthalate film. The film had a thickness of 0.002 inch (0.05 mm). The film was advanced at a line speed of about 6.6 ft/min (2 m/min) while the Example 1 composition was being coated. The coated film was transported through 12 feet of a forced air oven set to 74° C. until dry. The dried composition was then exposed to UV radiation from a curing station equipped with H-bulbs. The resulting planarization layer was approximately 4 to 5 microns thick.

### Examples 2-8

The coating composition of Example 1 was repeated for these examples but with the following changes in silica particle concentrations of approximately 5%, 10%, 15%, 21%, 26%, 31% and 36%, respectively. The resulting planarization layers were approximately 4-5 microns thick.

### Comparative Example 1

The coating composition of Example 1 was repeated for this example but without any silica particles. The resulting planarization layer was approximately 4-5 microns thick.

The surface roughness values for each of the Examples were measured with AFM using 5 by 5 micron area scans and the results provided in Table 1.

TABLE 1

| | Ave. | Ave. | Ave. | Ave. | |
|---|---|---|---|---|---|
| | Ra | Rq | Ra | Rq | |
| | (from | (from | (from | (from | |
| | 5 × 5 | 5 × 5 | 20 × 20 | 20 × 20 | Approx. |
| | micron | micron | micron | micron | Wt. % |
| Examples | scan) | scan) | scan) | scan) | Particles |
| Example 1 | 0.46 | 0.58 | | | 41 |
| Example 2 | 0.58 | 0.73 | | | 5 |
| Example 3 | 0.57 | 0.72 | | | 10 |
| Example 4 | 0.56 | 0.71 | | | 15 |
| Example 5 | 0.54 | 0.68 | | | 21 |
| Example 6 | 0.52 | 0.66 | | | 26 |
| Example 7 | 0.50 | 0.64 | | | 31 |
| Example 8 | 0.47 | 0.60 | | | 36 |
| Example 9 | 0.34 | 0.43 | 0.37 | 0.46 | 41 |
| Example 10 | 0.45 | 0.56 | 0.45 | 0.56 | 45 |
| Example 11 | 0.52 | 0.65 | 0.56 | 0.71 | 60 |
| Example 12 | 0.45 | 0.57 | 0.46 | 0.58 | 41 |
| Example 13 | 0.45 | 0.57 | 0.46 | 0.58 | 41 |
| Example 14 | 4.08 | 5.15 | 4.64 | 5.85 | 41 |
| Example 15 | 1.00 | 1.25 | 1.05 | 1.32 | 41 |
| Comparative | 0.70 | 0.88 | | | 0 |
| Example 1 | | | | | |
| Comparative | 0.65 | 0.81 | 0.64 | 0.80 | 0 |
| Example 2 | | | | | |
| Comparative | 0.58 | 0.72 | 0.61 | 0.77 | 0 |
| Example 3 | | | | | |

### Example 9

The coating procedure of Example 1 was followed except that the only acrylate used in the coating was SR-494 and the coating solution was diluted in IPA/Tol (not MEK). The coating solution was feed via syringe pump at 1.3 cc/minute to the 4 inch (102 mm) wide slot die with a 5 mil shim. The web speed was 2 m/min. Surface roughness values were measured for 5×5 micron and 20×20 micron scans with the results reported in Table 1.

### Comparative Example 2

A resin comprising mostly SR-494 and 1% by weight TPO-L was diluted to 50% by weight in IPA/Tol and coated as in Example 9. Surface roughness values were measured for 5×5 micron and 20×20 micron scans with the results reported in Table 1.

### Example 10

A zirconia sol available from NALCO (Naperville, Ill.) as product designation NALCO OOSSOO8 (150 grams @ 61.35 wt % ZrO2 having an 8 to 10 nm diameter) and MEEAA (7.24 grams) were charged to a 500 ml round bottom flask. 1-Methoxy-2-propanol (105 grams), HEAS (6.27 grams), Resin 1 (61.35 g grams), and PROSTABB (1.12 grams solution that was 5.0 weight percent in water) were charged into the flask. The 1-Methoxy-2-propanol and water were then removed via rotary evaporation. The resulting mixture was translucent forming a medium viscosity dispersion. The resulting composition contained approximately 45 weight percent ZrO₂ particles dispersed in a curable resin. The dispersion was dissolved in IPA/Tol at 50% solids and coated as in Example 9 after adding 0.66 g TPO-L. Surface roughness values were measured for 5×5 micron and 20×20 micron scans with the results reported in Table 1.

### Example 11

The zirconia sol available from NALCO (Naperville, Ill.) as product designation NALCO OOSSOO8 (150 grams @ 61.35 wt % ZrO2 having an 8 to 10 nm diameter) and MEEAA (7.30 grams) were charged to a 500 ml round bottom flask. 1-Methoxy-2-propanol (108 grams), HEAS (11.75 grams), Resin 1 (27.88 grams), and PROSTABB (1.00 grams solution that was 5.0 weight percent in water) were charged to the flask. The 1-Methoxy-2-propanol and water were then removed via rotary evaporation. The resulting mixture was translucent forming a viscous dispersion. The resulting composition contained approximately 60 weight percent ZrO₂ particles dispersed in a curable resin. The dispersion was dissolved in IPA/Tol at 50% solids after adding 0.70 grams of TPO-L. Surface roughness values were measured for 5×5 micron and 20×20 micron scans with the results reported in Table 1.

### Example 12

The coating preparation procedure of Example 1 was followed with IPA/Tol as the solvent and the substrate was coated using the coating conditions of Example 9. Surface roughness values were measured for 5×5 micron and 20×20 micron scans with the results reported in Table 1.

### Example 13

The coating preparation procedure of Example 1 was followed with IPA/Tol as the solvent and the substrate was coated using the coating conditions of Example 9. The surface treatment of the Nalco 2326 particles was changed to a more polar nature by silane-modification of the silica dispersion as follows: Nalco 2326 (450 g) was charged into a 1 qt jar. 1-methoxy-2-propanol (506.72 g), 3-(Methacryloyloxy)propyltrimethoxysilane (15.88 g) and Silquest A1230 (32.09 g) were mixed together and added to colloidal dispersion while stirring. The jar was sealed and heated to 8° C. for 16 hr. Surface roughness values were measured for 5×5 micron and 20×20 micron scans with the results reported in Table 1.

### Example 14

The coating preparation procedure of Example 1 was followed with IPA/Tol as the solvent and the substrate was coated using the coating conditions of Example 9. The surface treatment of the Nalco 2326 particles was changed to a more hydrophobic nature by silane-modification of the silica dispersion as follows: Nalco 2326 (450 g) was charged to a 1 qt jar. 1-methoxy-2-propanol (506.72 g), 3-(Methacryloyloxy)propyltrimethoxysilane (15.88 g) and BS1316 (14.98 g) were mixed together and added to colloidal dispersion while stirring. The jar was sealed and heated to 8° C. for 16 hr. The surface treated silica dispersion was combined with resin 1 and about lgram of 5% Prostabb by weight in water. Rotary evaporation of the mixture yielded a material so viscous that it would not flow from the flask. IPA/Tol was used to rinse the material from the flask and dilute to 50% by weight. TPO-L (0.59 grams) was added to the coating solution. Surface roughness values were measured for 5×5 micron and 20×20 micron scans with the results reported in Table 1.

### Example 15

The coating preparation procedure of Example 1 was followed with IPA/Tol as the solvent and the substrate was coated using the coating conditions of Example 9. The surface treatment of the Nalco 2326 particles was changed such that the particles would not react with the resin upon UV curing by silane-modification of the silica dispersion as follows: Nalco 2326 (450 g) was charged into a 1 qt jar. 1-methoxy-2-propanol (506.72 g), (2-Cyanoethyl)triethoxysilane (14.79) and BS1316 (14.99 g) were mixed together and added to the colloidal dispersion while stirring. The jar was sealed and heated to 8° C. for 16 hr. Surface roughness values were measured for 5×5 micron and 20×20 micron scans with the results reported in Table 1.

### Comparative Example 3

Another comparative example was made similar to Comparative Example 1 except IPA/Tol was used as the solvent and the coating conditions of Example 9 were followed. Surface roughness values were measured for 5×5 micron and 20×20 micron scans with the results reported in Table 1.

It is desirable for the planarized surface of the planarization layer to exhibit a surface hardness of at least about 2H, 3H, 4H, or harder, as determined by a pencil lead scratch test as given in ASTM D3363-05. It is also desirable for the planarized surface to meet or exceed the 00 rated steel wool hand scratch resistance test or to pass the abrasion resistance test as follows. The abrasion resistance of the cured films was tested cross-web to the coating direction by use of a mechanical device capable of oscillating a steel wool sheet adhered to a stylus across the film's surface. The stylus oscillated over a 60 mm wide sweep width at a rate of 210 mm/sec (3.5 wipes/sec) wherein a “wipe” is defined as a single travel of 60 mm. The stylus had a flat, cylindrical base geometry with a diameter of 3.2 cm. The stylus was designed for attachment of additional weights to increase the force exerted by the steel wool normal to the film's surface. The #0000 steel wool sheets were “Magic Sand-Sanding Sheets” available from Hut Products Fulton, Mo. The #0000 has a specified grit equivalency of 600-1200 grit sandpaper. The 3.2 cm steel wool discs were die cut from the sanding sheets and adhered to the 3.2 cm stylus base with 3M brand Scotch Permanent Adhesive Transfer tape. A single sample was tested for each example, with a 1000 gram weight applied and 50 wipes employed during testing. The sample was then visually inspected for scratches. Ideally no wear or scratches should appear, but samples exhibiting only a few scratches pass the test. Once coated and polymerized, the resulting planarization layer of Example 1 formed a planarized surface that can resist being scratched by hand with 0 rated steel wool without substantial surface scratches, if any. Examples 9, 12, and 13 as well as the comparative examples 2 and 3 passed the abrasion resistance test described above.

The surface roughness for each coated film can be evaluated with tapping mode atomic force microscopy. Samples were imaged in air under ambient conditions using a Digital Instruments Dimension 5000 SPM System scanning probe microscope with a Nanoscope IIIa controller, commercially available from Veeco Metrology Inc. of Santa Barbara, Calif. Scanning was done in an intermittent contact with the sample surface using TappingMode™, which is a patented technique (Veeco Instruments) that maps topography by lightly tapping the surface with an oscillating probe tip. The cantilever's oscillation amplitude changes with sample surface topography, and the topography image is obtained by monitoring these changes and closing the z feedback loop to minimize them. The amplitude of the cantilever oscillation in TappingMode™ is typically on the order of a few 10's of nanometers. Tips used were anisotropic Si probes (OTESP, Veeco Inc.) with spring constant ˜42 N/m (12-103 N/m) and resonance frequency ˜300 kHz (200-400 kHz). Additionally, the instrument was equipped with a custom-built, close-loop large area scanner (180×180 μm²) with control electronics obtained from nPoint Inc. of Madison, Wis. All images included 512×512 data points. Image analysis and measurements were performed using the algorithms contained in Nanoscope 5.30 software. Flattening or plane-fitting was applied as necessary to correct for tilt in some images.

This invention may take on various modifications and alterations without departing from its spirit and scope. Accordingly, this invention is not limited to the above-described embodiments but is to be controlled by the limitations set forth in the following claims and any equivalents thereof. For example, other potential acrylate materials that may be useful in coating compositions according to the present invention can be found in U.S. Pat. No. 5,104,929. All patents and patent applications cited above, including those in the Background section, are incorporated by reference into this document in total.

1. A substrate coated with a composition so as to form a planarizing layer defining a planarized surface of said substrate having an average RMS surface roughness equal to or less than about 0.8 nm, said composition comprising in polymerized form at least one acrylate containing monomer, oligomer, or resin and a plurality of inorganic oxide particles that are smaller than or equal to 15 nm in size.

2. The substrate according to claim 1, wherein the planarized surface of said substrate has an RMS surface roughness equal to or less than 0.6 nm.

3. The substrate according to claim 1, wherein said composition comprises in polymerized form a blend of two or more acrylate containing monomers, oligomers, resins or a combination thereof.

4. The substrate according to claim 1, wherein said composition comprises at least about 5% by weight of said inorganic oxide particles.

5. The substrate according to claim 1, wherein said inorganic oxide particles are of a size within a range of from about 1 nm up to about 10 nm.

6. The substrate according to claim 1, wherein said inorganic oxide particles comprise silica particles.

7. The substrate according to claim 1, wherein said composition in its pre-polymerized form is radiation curable.

8. The substrate according to any claim 1, wherein said composition comprises silica particles of about 5 nm in size and in concentrations in the range of from about 5% to about 40% by weight.

9. The substrate according to claim 1, wherein the planarized surface of said planarization layer has a hardness of about 2H or harder.

10. The substrate according to claim 1, wherein the planarized surface of said planarization layer is coated with at least one of a metallic layer and a barrier layer.

11. A method of planarizing a surface of a substrate, said method comprising:
providing a substrate having a major surface;
providing a composition comprising at least one acrylate containing monomer, oligomer, or resin and a plurality of inorganic oxide particles that are smaller than or equal to 15 nm in size;
coating the major surface of the substrate with the composition; and
polymerizing the coated composition so as to form a planarizing layer defining a planarized surface having an RMS surface roughness equal to or less than about 0.8 nm.

12. The method according to claim 11, further comprising cleaning the major surface of the substrate before it is coated with the composition.

13. The method according to claim 12, wherein the major surface of the substrate is cleaned so as to be substantially free of particles having a size equal to or larger than 3 microns.

14. The method according to claim 11, wherein the planarized surface has an RMS surface roughness equal to or less than 0.6 nm.

15. The method according to claim 11, wherein the composition comprises a blend of two or more acrylate containing monomers, oligomers, resins or a combination thereof.

16. The method according to claim 11, wherein the composition comprises at least about 5% by weight of the inorganic oxide particles.

17. The method according to claim 11, wherein the inorganic oxide particles are of a size within a range of from about 1 nm up to about 10 nm.

18. The method according to claim 11, wherein the composition comprises inorganic oxide particles in the form of a dispersion of colloidal particles.

19. The method according to claim 18, wherein the colloidal particles comprise silica particles.

20. The method according to claim 11, wherein the composition is a radiation curable composition.

21. The method according to claim 11, wherein the composition comprises colloidal silica particles of about 5 nm in size and in concentrations in the range of from about 5% to about 40% by weight.

22. The method according to claim 11, wherein the substrate is a flexible web substrate of indefinite length, and the major surface is coated with the composition while the web substrate is moving in a direction parallel to its longitudinal axis.

23. The method according to claim 11, further comprising:
coating the planarized surface with at least one of a metallic layer and a barrier layer.
